(19) United States
(12) Patent Application Publication
(10) Pub. No.: US 2026/0231681 A1
(43) Pub. Date: Aug. 6, 2026

(54) THERMOELECTRIC ENERGY SYSTEM USING INTERMITTENT GAS PILOT FOR POWER MANAGEMENT

(71) Applicant: RESIDEO LLC, Golden Valley, MN (US)

(72) Inventors: Tony R. Khosla, Maple Grove, MN (US); John Douglas Mitchell, Maple Grove, MN (US); Peter Anderson, Saint Paul, MN (US); Timothy J. Smith, Minneapolis, MN (US)

(73) Assignee: RESIDEO LLC, Golden Valley, MN (US)

(21) Appl. No.: 19/448,541

(22) Filed: Jan. 14, 2026

Related U.S. Application Data
(60) Provisional application No. 63/753,656, filed on Feb. 4, 2025.

(51) Int. Cl. H10N 10/13; F24H 1/18; H10N 10/851; H10N 10/852; H10N 19/00

(52) U.S. Cl. CPC H10N 10/13; F24H 1/186; H10N 19/101; F24H 2240/01; F24H 2240/08; H10N 10/852; H10N 10/8556

(57) ABSTRACT

The disclosure presents a thermoelectric energy system leveraging an intermittent gas pilot light for power management in gas-powered devices. The system generates electrical power via a thermoelectric device with a hot side absorbing heat from a pilot flame and a cold side linked to a heat sink, creating a temperature differential for power generation. The system may include multiple thermopiles, connected in series for higher voltage, efficiently powering devices like valve actuators, powered anodes, and Wi-Fi transceivers. The system includes a gas burner platform configured for intermittent heat production, which includes a pilot flame. The thermoelectric device converts the heat from the flame into electrical power, which is stored for later use. Advanced materials like bismuth telluride enhance power generation. A controller manages system operations, ensuring adequate power storage and enabling remote monitoring and control. The system offers a reliable, efficient power solution for diverse industrial and residential applications.

### RELATED APPLICATION(S)

This application claims the benefit of and priority to U.S. Provisional Application No. 63/753,656, filed Feb. 4, 2025, the contents of which are incorporated herein by reference in its entirety.

### FIELD OF THE DISCLOSURE

The disclosed system relates generally to thermoelectric energy systems and, more specifically, to systems utilizing an intermittent gas pilot flame for electrical power generation in gas-powered platforms.

### SUMMARY OF THE DISCLOSURE

The disclosure is directed to a thermoelectric energy system that utilizes an intermittent gas pilot light for power management in gas-powered devices. In some embodiments, the system is configured to generate electrical power through a thermoelectric device, which comprises a hot side and a cold side. The hot side absorbs heat produced by a flame provided by an intermittent pilot, while the cold side is coupled to a heat sink, creating a temperature difference that facilitates power generation. In some embodiments, the thermoelectric device includes multiple thermopiles, which may be connected in series to enhance voltage output or in parallel to increase current capacity. These configurations enable the system to efficiently power various electronic devices, such as valve actuators, powered anodes, Wi-Fi transceivers, and batteries, which have high energy demands but may not be located close to a utility power source.

In some embodiments, the system includes a gas burner platform that intermittently produces heat, which may be used to warm water in a water heater, as a non-limiting example. During this process, the thermoelectric device converts thermal energy into electrical power, which is stored in a power storage device such as a battery. This stored power is then utilized to operate other electronic devices when the gas burner is inactive. In some embodiments, one or more thermocouple and/or thermopiles include advanced materials, such as bismuth telluride and silicon-germanium, which increase power generation to an unconventional level.

A controller manages the operation of the system, including the ignition of the thermoelectric pilot and the regulation of power distribution to auxiliary devices. The controller ensures that the power storage maintains an adequate charge level, enabling continuous operation of the system. The system's architecture supports connectivity with user equipment and access points, enabling remote monitoring and control through a network, while also powering the access point itself in some embodiments.

The thermoelectric energy system described herein is applicable in various industrial and residential settings, offering a reliable and efficient solution for power generation in gas-powered devices. Its innovative use of thermoelectric technology and advanced materials positions it as a versatile component in modern energy systems, capable of supporting a wide range of applications.

### DESCRIPTIONS OF THE DRAWINGS

The features, and advantages of the disclosure will be apparent from the following description of embodiments as illustrated in the accompanying drawings, in which reference characters refer to the same parts throughout the various views. The drawings are not necessarily to scale, emphasis instead being placed upon illustrating principles of the disclosure:

FIG. 1 is a block diagram of an example configuration within which the system and methods disclosed herein could be implemented according to some embodiments of the present disclosure;

FIG. 2 is a block diagram illustrating components of the system embodied as a water heater according to some embodiments of the present disclosure;

FIG. 3 shows a non-limiting example workflow in according to some embodiments of the present disclosure;

FIG. 4 illustrates an example algorithmic step execution according to some embodiments of the present disclosure;

FIG. 5 depicts an example implementation of a framework architecture according to some embodiments of the present disclosure;

FIG. 6 depicts an example implementation of a framework architecture according to some embodiments of the present disclosure; and

FIG. 7 is a block diagram illustrating a computing device showing an example of a client or server device used in various embodiments of the present disclosure.

### DETAILED DESCRIPTION

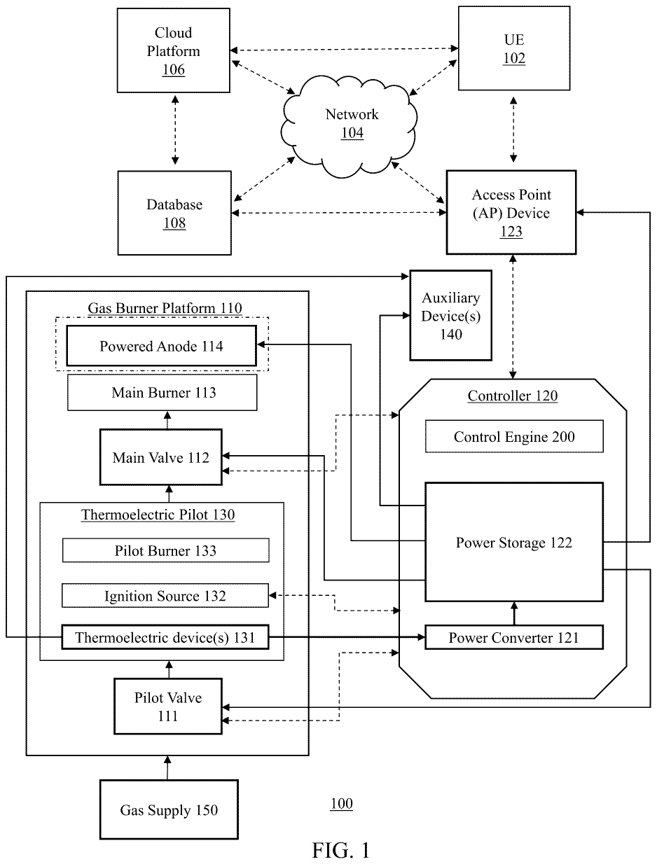

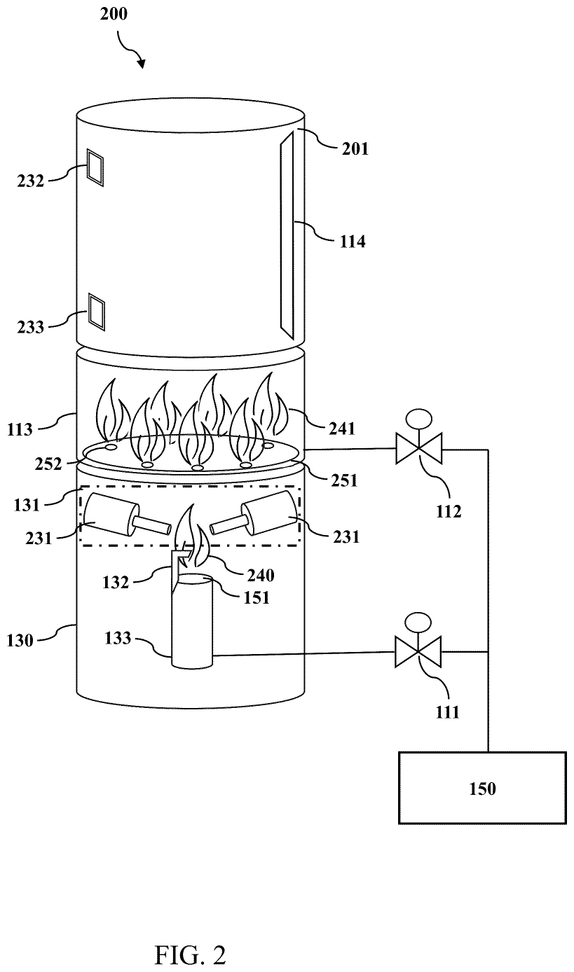

FIG. 1 illustrates a non-limiting system 100 that includes a gas burner platform 110 equipped with a flame-powered thermoelectric pilot 130. In some embodiments, the thermoelectric pilot 130 includes an ignition source 132 configured to light a pilot burner 133, which may be executed intermittently and/or when the flame is needed to generate electricity as further described herein. In some embodiments, the gas burner platform 110 includes a main burner 113 which is ignited by the thermoelectric pilot 130. In some embodiments, the main burner 113 includes a burner disc 251 that includes one or more main flame outlets 252 configured to burn gas and/or arranged to heat a fluid, such as water. In some embodiments, the thermoelectric pilot 130 includes a pilot flame outlet 151 configured to light the main burner 113. Although FIG. 2 shows the thermoelectric pilot 130 beneath the main burner 251 to better illustrate aspects of the system 100, the thermoelectric pilot 130 can be placed anywhere that the flame 240 can ignite the main burner 113.

In some embodiments, the system includes a controller 120, which manages the operation of a main valve 112 and a pilot valve 111, both of which are connected to a gas supply. In some embodiments, the thermoelectric pilot 130 includes a thermoelectric device 131. The thermoelectric device 131 may include one or more thermopiles 231 configured to be thermally coupled with the flame 240 of the pilot burner 133, as illustrated in FIG. 2. In some embodiments, the thermoelectric device is configured to convert the thermal energy generated by the pilot burner 133 into electrical energy as further described herein.

In some embodiments, the system 100 includes a controller 120 that includes and/or is operatively coupled to a power storage 122, which stores the electrical energy generated by the thermoelectric device 131. In some embodiments, the controller 120 is configured to direct power from the power storage 122 to various components, including the ignition source 132, pilot valve 111, main valve 112, power anode 114, and/or auxiliary devices 140 as needed for system operation.

As depicted in FIG. 1, the control 120 is operatively connected to a database 108, the main valve 112, the pilot valve 111, the thermoelectric device 131, access point device 123 and/or auxiliary device 140. While shown as part of a network in FIG. 1, at least a portion of database 108 (i.e., non-transitory computer readable media) may reside in and/or be integral to controller 120 in accordance with some embodiments. In some embodiments, the controller 120 monitors the system's operational parameters via one or more auxiliary devices 140, which may include various powered sensors, for example, and regulates the pilot valve 111 and main valve 112 according to predefined operational setpoints.

To prevent excessive cycling of the main burner 113, in some embodiments, the system 100 executes a setpoint strategy that includes an upper and lower threshold. The control 120 activates the thermoelectric pilot 130 and/or main valve 112 when the operational parameters fall below the lower threshold. In some embodiments, the control 120 deactivates the thermoelectric pilot 130 and/or main valve 112 upon reaching an upper threshold. This differential, known as the operational dead band, is calibrated to achieve optimal cycling rates under steady-state conditions, which is useful where the system 100 is integrated into a water heater 200, as a non-limiting example.

During operation, the control 120 initiates an ignition sequence by opening the pilot valve 111 to supply gas from the gas supply 150 to the thermoelectric pilot 130. Upon gas delivery, the controller 120 activates the ignition source 132 to ignite the pilot burner 133. Subsequently, the controller 120 opens the main valve 112 to ignite the main flame 241 in the main burner 113 using the pilot flame 240. The thermoelectric device 131, exposed to the pilot flame 240, generates electrical energy, which is stored in the power storage 122. The controller 120 monitors the charge level of the power storage 122, ensuring it remains at or above a specified threshold. If the charge level is sufficient, the controller 120 may limit or cease energy transfer from the thermoelectric device 131 to the power storage 122. Conversely, if the charge level falls below the threshold, the controller 120 facilitates energy transfer from the thermoelectric device 131 to recharge the power storage 122 by sending a signal to ignite pilot burner 133. The controller 120, the main valve 112, the pilot valve 111, the thermoelectric device 131, access point device 123 and/or auxiliary device 140 may rely exclusively on the power storage 122 for its operational power, necessitating the maintenance of an adequate charge level for the continued functionality of the system 100.

In some embodiments, the power storage 122 is configured to deliver operating power to one or more components of the gas burner platform 110, as well as one or more auxiliary devices 140. In some embodiments, an auxiliary device 140 may be associated with gas burner platform 110, such as temperature sensor 232 and/or leak detector 233. In some embodiments, an auxiliary device 140 may not be associated with gas burner platform 110 but may nonetheless receive power from power storage 122 in a novel arrangement as described herein. In some embodiments, the power storage 122 may deliver operating power to the controller 120. In some embodiments, the power storage 122 may be coupled to a power generation circuit that includes a power converter 121 configured to receive energy from thermoelectric device 131 and supply the energy to the power storage 122. The power storage 122 may include any of a variety and/or combination of battery types, such as nickel cadmium batteries and lithium-ion batteries. Additionally, or alternatively, the power storage 122 may include one or more capacitors configured to store energy in accordance with some embodiments.

In some embodiments, during a heating phase, the thermoelectric pilot 130 remains ignited, thereby exposing the thermoelectric device 131 to the pilot flame 240. This exposure results in the generation of electrical power, which the controller 120 utilizes to recharge the power storage 122. In some embodiments, the thermoelectric pilot 130 imparts less thermal energy than the main burner 113, resulting in a slower increase in temperature within the gas platform 110. In some embodiments, at least a portion of the heat produced by the pilot flame 240 is configured to heat water in tank 201, thereby increasing the efficiency of the system by utilizing the excess heat being provided for electrical generation. Although pilot burner 133 does not elevate the temperature as rapidly as when the main burner 113 is active, using pilot burner 133 as a heat source during non-peak periods does permit the thermoelectric pilot 130 to remain ignited for an extended duration within the operational cycle. Consequently, the thermoelectric device 131 can generate power over a prolonged period, enhancing the recharging process of the power storage 122.

In some embodiments, the heating may persist until the power storage 122 achieves full charge, or may only stay active long enough to generate a pre-determined amount of power for device manipulation. In some embodiments, the controller may initiate thermoelectric pilot 130 for power storage 122 to partially recharge, maintain charge, and/or slow the depletion of energy. In some embodiments, upon reaching full charge, the controller 120 may issue a directive to both the thermoelectric pilot 130 and the main burner 113 to engage in a combined operational mode, wherein both elements are activated for a subsequent heating phase until the gas burner platform 110 attains an upper temperature setpoint threshold. Once the controller 120 ascertains that the power storage 122 is fully charged, the controller 120 may cease energy transfer from the thermoelectric device 131 to the power storage 122, or alternatively, maintain a minimal energy flow to sustain the charge level.

To better use the energy being generated by thermoelectric pilot 130, in some embodiments, the system is configured to power one or more auxiliary devices 140, which may include devices that require steady and/or substantial energy consumption, such as a camera, as a non-limiting example. In some embodiments, the controller 120 may ignite the thermoelectric pilot 130 in response to receiving an electrical signal indicating a power demand from auxiliary devices 140. In this manner, the controller 120 may activate the thermoelectric pilot 130 using ignition source 132 to ensure that the thermoelectric device 131 will supply sufficient energy to the power storage 122, allowing the system to maintain auxiliary devices 140 in an operational state. In some embodiments, the controller 120 may activate power converter 121, which directs current from the thermoelectric device 131 through the power storage 122.

In some embodiments, the power converter 121 is used in the transfer of energy from the thermoelectric device 131 to the power storage 122 when the electrical characteristics of the thermoelectric device 131 do not align with the requirements for charging power storage 122. In some embodiments, the thermoelectric device 131 can generate a relatively low voltage output, which can include the millivolt range, which may be insufficient for charging power storage devices that typically require higher and regulated voltages, such as 3.7 volts for lithium-ion or 12 volts for lead-acid configurations. The power converter 121, which may include a boost converter or charge pump, as non-limiting examples, addresses these mismatches by converting the low voltage from the thermoelectric device 131 to the higher, stable voltage needed for charging the power storage 122. In some embodiments, the power converter 121 can accumulate the low power generated by the thermoelectric device 131, store it in an electrical storage device (e.g., battery, capacitor), and release it in bursts to charge the power storage 122 efficiently, ensuring voltage regulation and stable current delivery.

In some scenarios, while the thermoelectric device 131 supplies energy to the power storage 122 and the controller 120 receives the signal indicating power demand from auxiliary devices 140, the power storage 122 may directly supply energy to auxiliary devices 140 to maintain their operation while being charged by thermoelectric device 131. The controller 120 may keep the thermoelectric pilot 130 in a continuously ignited state during periods when it receives signals indicating power demand from auxiliary devices 140, and/or maintain the thermoelectric pilot 130 in an active state for as long as the auxiliary devices 140 need power. Alternatively, the controller 120 may sustain the ignition of the thermoelectric pilot 130 until the energy stored in the power storage 122 reaches a predetermined level. In certain cases, the controller 120 may continue to keep the thermoelectric pilot 130 ignited until the power storage 122 approaches its maximum capacity. In one or more examples, the controller 120 may extinguish or allow the thermoelectric pilot 130 to extinguish once the energy stored in the power storage 122 reaches a satisfactory level, or the demand from one or more auxiliary devices 140 are met. This control feature is also useful for ensuring enough energy is available for the powered anode 114, which may be used in water heater 200 (or any system described herein) to prevent corrosion.

In some embodiments, if water temperature is low and/or if recharging is required, the thermoelectric pilot 130 is configured to be lit by the controller 120. In some embodiments, if water temperature is low, the main burner 113 is configured to be lit by the controller 120 via the thermoelectric pilot 130. In some embodiments, if water temperature is not low, the controller 120 is configured to not light the main burner 113. In some embodiments, when the temperature of water in the tank 201 reaches a setpoint, the controller 120 is configured to turn the main burner 113 off. In some embodiments, the controller 120 is configured to turn the thermoelectric pilot 130 off when a charge setpoint for power storage 122 has been achieved. In some embodiments, the controller is configured to ensure that the main burner 113 is not producing heat when the thermoelectric pilot 130 is off. In some embodiments, the controller is configured to light the main burner 113 a plurality of times during a continuous charge of the power storage 122 using the thermoelectric device 131.

In some embodiments, thermopiles are formed by connecting a plurality (e.g. 20 or more) thermocouples in series. In some embodiments, the thermoelectric device 131 is configured to generate power through a plurality of thermocouples (to create a thermopile) and/or a plurality of thermopiles arranged in series. In some embodiments, the series configuration is configured to increase the voltage output of the device for components requiring higher voltage levels for efficient operation. By connecting multiple thermocouples in series, the device sums the individual voltages generated by each thermocouple, resulting in a significantly higher total voltage output.

In some embodiments, the thermoelectric device 131 is configured to maximize power output through the use of a plurality of thermocouples and/or thermopiles arranged in parallel. In some embodiments, a parallel configuration is configured to enhance the current producing capacity of the thermoelectric device 131, thereby increasing the total available power for various applications as shown in FIG. 1, for example. By connecting multiple thermocouples and/or thermopiles in parallel, the device can maintain a consistent voltage output while significantly boosting the current, enabling the system 100 to powering larger components such as pilot valve 111, main valve 112, powered anode 114, and/or multiple auxiliary devices 140 simultaneously. In some embodiments, the thermoelectric device includes a plurality of thermocouples and/or thermopiles arranged in parallel and in series to obtain a voltage and/or current flow suitable for one or more applications described herein.

In some embodiments, the novel series arrangement described herein achieves higher voltage levels without the need for additional external components, such as voltage multipliers or transformers. This voltage enhancement arrangement simplifies the overall system design and reduces the complexity and cost associated with external voltage-boosting components. The increased voltage output is particularly beneficial for charging power storage units, such as power storage 122, that require specific voltage levels to operate efficiently, and may be used to power auxiliary devices 140 directly, such as temperature sensor 232 and/or leak detector 233.

Additionally, the series configuration allows the thermoelectric device to maintain a consistent current flow, which provides a stable power delivery to directly power auxiliary devices 140, for example. In some embodiments, the series arrangement of thermocouples and/or thermopiles ensures that the device can reliably power applications that demand a steady voltage supply, even under varying thermal conditions.

As illustrated in FIG. 2, in some embodiments, the system 100 includes a plurality of individual thermopiles surrounding a single pilot flame. In some embodiments, one or more of the plurality of individual thermopiles are connected in series and/or in parallel as discussed above. In some embodiments, one or more of the plurality of individual components are configured to directly supply electrical energy to an auxiliary component 140, where the voltage and/or current out of the one or more thermopiles is configured to match and/or be compatible with the requirements of the auxiliary component 140. In some embodiments, one or more auxiliary components 140 include a power converter for regulating the incoming power as discussed above.

FIG. 2 shows the system integrated into a water heater 200 as a non-limiting example, however the example embodiment should not be construed as limiting. In some embodiments, the gas burner platform 110 may be integrated into various home and commercial systems, leveraging its ability to provide controlled and efficient heat. In some embodiments, the gas burner platform 110 may be utilized in the chemical industry in processes such as distillation and chemical reactions. In some embodiments, the gas burner platform 110 may be employed in the food industry in ovens and stoves, providing the necessary heat for cooking and baking equipment. In some embodiments, the gas burner platform 110 may be a component in furnaces where it is used to heat large volumes of air or other gases, such as those used in metalworking and glassmaking industries, for example. In some embodiments, gas burner platform 110 platform may be utilized in residential and commercial heating systems, serving as the primary heat source in boilers, converting gas into thermal energy to warm water or air circulated throughout a building.

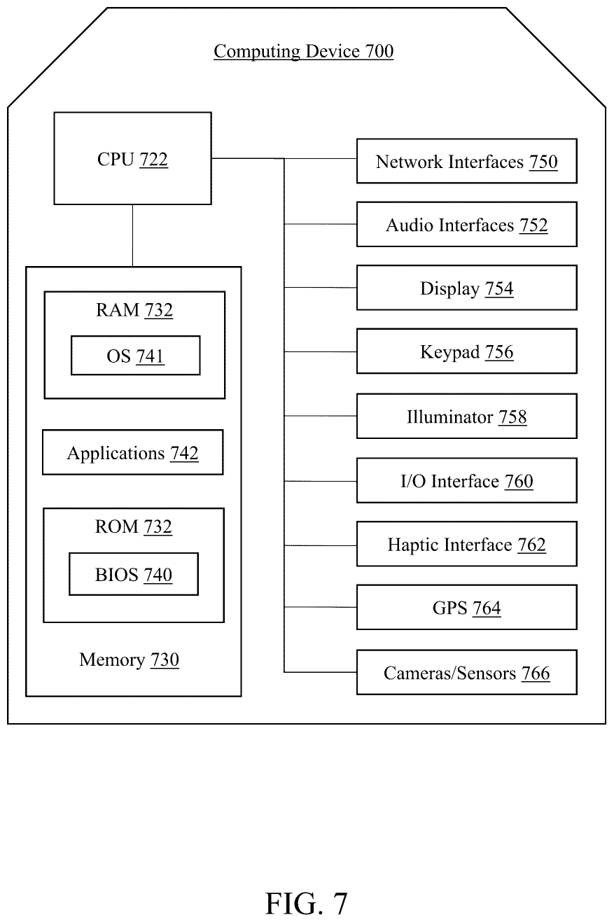

Turning back to FIG. 1, system 100 is depicted as including user equipment (UE) 102 (e.g., a client device, as mentioned above and discussed below in relation to FIG. 7), access point (AP) device 123, network 104, cloud platform 106, database 108, and/or control engine 200. In some embodiments, at least a part of control engine 200 resides on controller 120, where in some embodiment at least part of control engine 200 may be executed using cloud platform 106. It should be understood that while system 100 is depicted as including such components, it should not be construed as limiting, as one of ordinary skill in the art would readily understand that varying numbers of UEs, AP devices, peripheral devices, cloud systems, databases and networks can be utilized; however, for purposes of explanation, system 100 is discussed in relation to the example depiction in FIG. 1.

According to some embodiments, UE 102 can be any type of device, such as, but not limited to, a desk top computer, a server, a mobile (smart) phone, tablet, laptop, sensor, IoT device, autonomous machine, appliance, and/or any device equipped with a cellular and/or wireless or wired transceiver. For example, UE 102 can be a smart phone with various Apps installed, which can enable the configuration and/or monitoring of system 100.

In some embodiments, one or more auxiliary devices 140 can be connected to UE 102, and can be any type of device, such as, but not limited to, a speaker, a sensor, a camera, and the like. In some embodiments, auxiliary devices 140 can be any type of device that is connectable to UE 102 via any type of known or to be known pairing mechanism, including, but not limited to, WiFi, Bluetooth™, Bluetooth Low Energy (BLE), NFC, and the like, which may be provided by AP 123.

According to some embodiments, AP device 123 includes a device that creates a wireless local area network (WLAN) for the location. According to some embodiments, the AP device 112 can be, but is not limited to, a router, switch, hub and/or any other type of network hardware that can project a WiFi signal to a designated area. In some embodiments, controller 120 may be communicatively coupled to AP device 123, and send and receive data through network 104 to control various operations.

In some embodiments, network 104 can be any type of network, such as, but not limited to, a wireless network, cellular network, the Internet, and the like (as discussed above). Network 104 facilitates connectivity of the components of system 100, as illustrated in FIG. 1. Some non-limiting smart home networks compatible with system 100 include Matter®, Z-wave®, or Zigbee®. In some embodiments, network 104 includes a hub configured to enable the controller 100 to connect to the internet via a router, such as a home router, which may include communications with a cloud platform 106.

According to some embodiments, cloud platform 106 may be any type of cloud operating platform and/or network-based system upon which applications, operations, and/or other forms of network resources may be located. For example, platform 106 may be a service provider and/or network provider from where services and/or applications may be accessed, sourced or executed from. For example, platform 106 can represent the cloud-based architecture associated with a smart home or network provider, which has associated network resources hosted on the internet or private network (e.g., network 104), which enables (via control engine 200) the control and management of system 100 discussed herein.

In some embodiments, cloud platform 106 may include a server(s) and/or a database of information which is accessible over network 104. In some embodiments, a database 108 of cloud platform 106 may store a dataset of data and metadata associated with local and/or network information related to a user(s) of the components of system 100 and/or each of the components of system 100 (e.g., UE 102, AP device 112, and the services and applications provided by cloud platform 106 and/or control engine 200). In some embodiments, at least a portion of database 108 is integral to controller 120.

In some embodiments, for example, cloud platform 106 can provide a private/proprietary management platform, whereby control engine 200, discussed infra, corresponds to the novel functionality platform 106 enables, hosts and provides to a network 104 and other devices/platforms operating thereon.

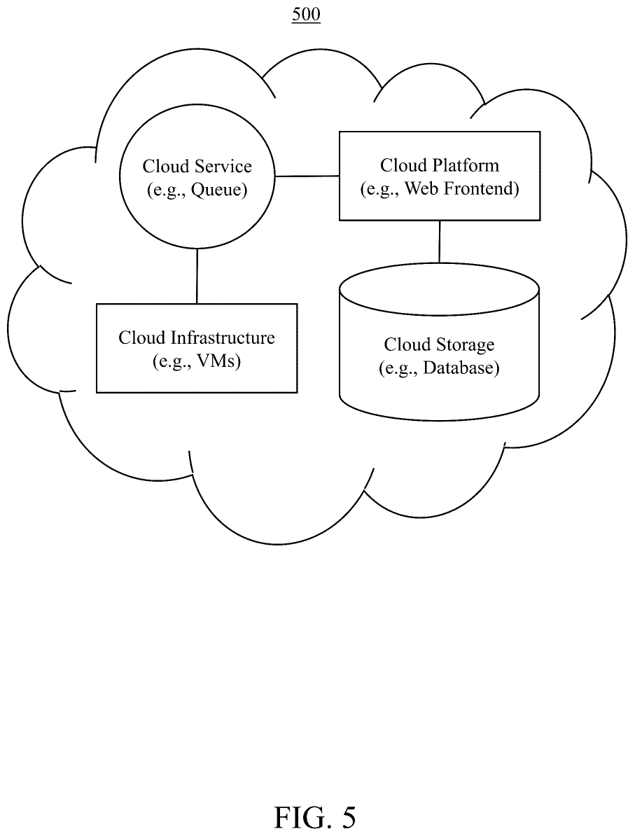

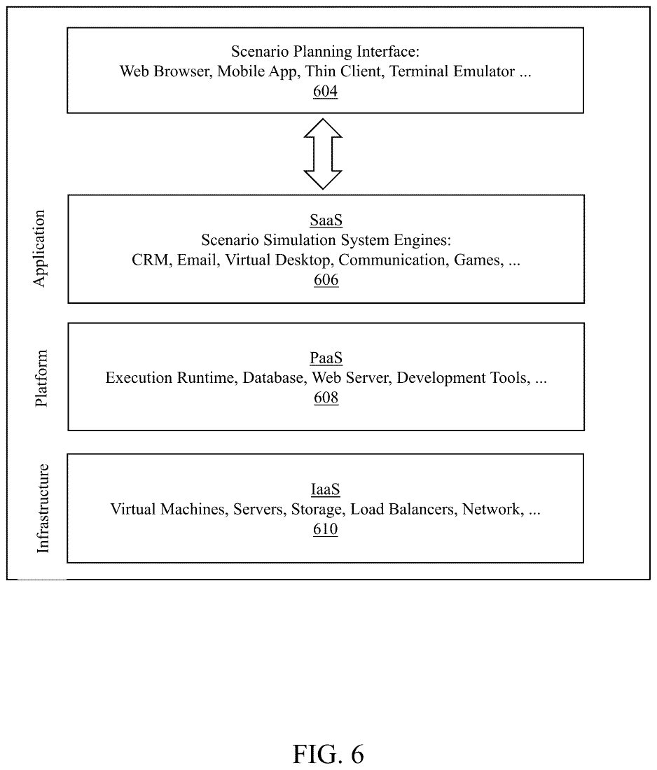

Turning to FIGS. 5 and 6, in some embodiments, the exemplary computer-based systems/platforms, the exemplary computer-based devices, and/or the exemplary computer-based components of the present disclosure may be specifically configured to operate in a cloud computing/architecture 500 such as, but not limiting to: infrastructure as a service (IaaS) 610, platform as a service (PaaS) 608, and/or software as a service (Saas) 606 using a web browser, mobile app, thin client, terminal emulator or other endpoint 604. FIGS. 5 and 6 illustrate schematics of non-limiting implementations of the cloud computing/architecture(s) in which the exemplary computer-based systems for administrative customizations and control of network-hosted application program interfaces (APIs) of the present disclosure may be specifically configured to operate.

According to some embodiments, database 108 may correspond to a data storage for a platform (e.g., a network hosted platform, such as cloud platform 106, as discussed supra) or a plurality of platforms. Database 108 may receive storage instructions/requests from, for example, control engine 200 (and associated microservices), which may be in any type of known or to be known format, such as, for example, standard query language (SQL). According to some embodiments, database 108 may correspond to any type of known or to be known storage, for example, a memory or memory stack of a device, a distributed ledger of a distributed network (e.g., blockchain, for example), a look-up table (LUT), and/or any other type of secure data repository.

Control engine 200, as discussed above and further below in more detail, can include components for the disclosed functionality. According to some embodiments, control engine 200 may be a special purpose machine or processor and can be hosted by a device on network 104, within cloud platform 106, on AP device 112 and/or on UE 102. In some embodiments, control engine 200 may be hosted by a server and/or set of servers associated with cloud platform 106.

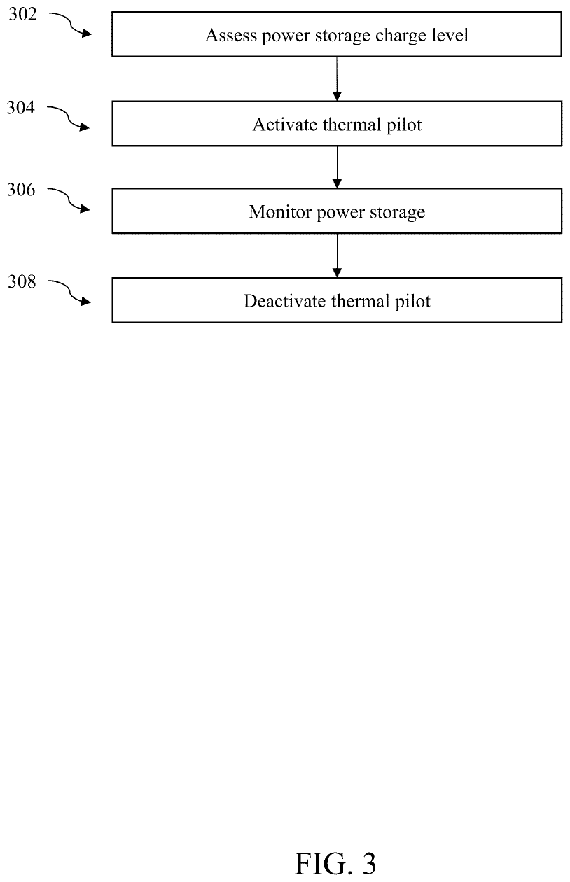

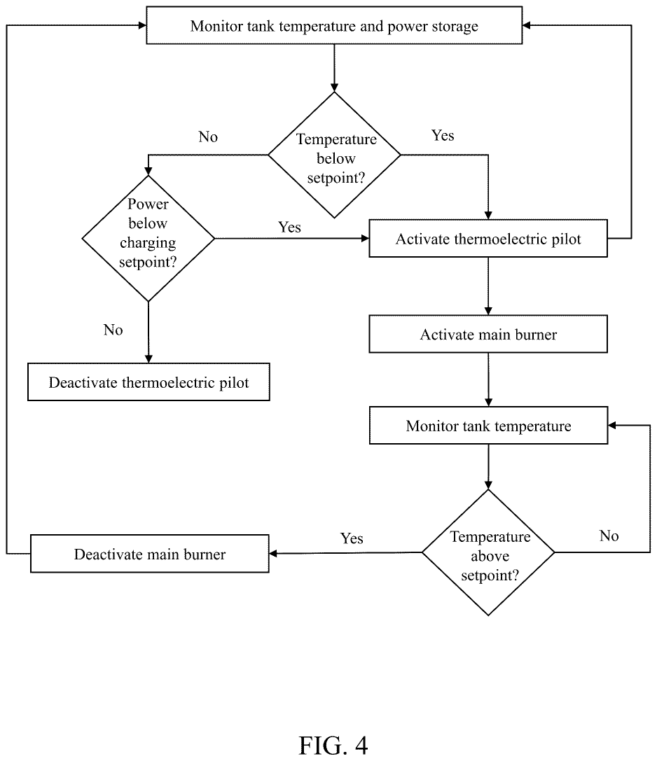

According to some embodiments, as discussed in more detail below, control engine 200 may be configured to implement and/or control a plurality of services and/or microservices, where each of the plurality of services/microservices are configured to execute a plurality of workflows associated with performing the disclosed application control and management framework. Non-limiting embodiments of such workflows are provided below in relation to at least FIGS. 3-4.

According to some embodiments, as discussed above, control engine 200 may function as an application provided by cloud platform 106. In some embodiments, control engine 200 may function as an application installed on a server(s), network location and/or other type of network resource associated with cloud platform 106. In some embodiments, control engine 200 may function as application installed and/or executing on UE 102 (and/or AP device 112, in some embodiments). In some embodiments, such application may be a web-based application accessed by AP device 112 and/or UE over network 104 from cloud platform 106. In some embodiments, control engine 200 may be configured and/or installed as an augmenting script, program or application (e.g., a plug-in or extension) to another application or program provided by cloud platform 106 and/or executing on AP device 112 and/or UE 102.

Turning to FIG. 3, process 300 provides a non-limiting example workflow for the disclosed control framework in accordance with some embodiments. According to some embodiments, process 300 provides non-limiting embodiments for activation of thermoelectric pilot 130, for which the disclosed framework (e.g., via control engine 200) can control, manage, and/or manipulate the generation of power for various system components. Steps described in the figures represent both an execution of a computer algorithm and a method of implementing the system.

At step 302, the controller 120 assesses the charge level of the power storage 122 to determine if it remains above a specified charge threshold. At step 304, if the charge level fall to a lower setpoint threshold, the controller 120 activates the thermoelectric pilot 130 to provide heat to thermoelectric device 131. At step 306, the controller 120 monitors the power storage 122, and if an upper power setpoint is reached, the controller ceases operation of the thermoelectric pilot 130 at step 308.

Turning to FIG. 4, flowchart 400 provides a non-limiting example embodiments of algorithm steps for the disclosed control framework. In some embodiments, the algorithm begins by monitoring the water tank 201 temperature using temperature sensor 232 and the charge level of the power storage 122. First, the system evaluates whether the water tank 201 temperature is below a predefined setpoint. If the temperature is below the setpoint, the controller 120 activates the thermoelectric pilot to initiate heating and subsequently activates the main burner 113 to raise the water temperature. Once these components are activated, the controller 120 continues to monitor the water tank temperature to determine if it exceeds the upper setpoint threshold. If the temperature rises above this threshold, the controller 120 deactivates the thermoelectric pilot 130 and/or the main burner 113 to prevent overheating.

In some embodiments, if the water tank 201 temperature is not below the setpoint, the system evaluates the charge level of the power storage 122. If the charge level is below a predefined charging threshold, the thermoelectric pilot 130 remains and/or becomes active to generate sufficient electric power via the thermopile 231, which may occur while the main burner 113 remains inactive. If the charge level is adequate, the controller 120 deactivates the thermoelectric pilot 130 to conserve fuel.

In some embodiments, such computational analysis can involve control engine 200 executing any type of known or to be known computational analysis technique, algorithm, mechanism or technology. In some embodiments, control engine 200 may include a specific trained artificial intelligence/machine learning model (AI/ML), a particular machine learning model architecture, a particular machine learning model type (e.g., convolutional neural network (CNN), recurrent neural network (RNN), autoencoder, support vector machine (SVM), and the like), or any other suitable definition of a machine learning model or any suitable combination thereof.

In some embodiments, control engine 200 may be configured to utilize one or more AI/ML techniques chosen from, but not limited to, computer vision, feature vector analysis, decision trees, boosting, support-vector machines, neural networks, nearest neighbor algorithms, Naive Bayes, bagging, random forests, logistic regression, and the like. By way of a non-limiting example, control engine 200 can implement an XGBoost algorithm for regression and/or classification to analyze the sensor data, as discussed herein.

According to some embodiments, the AI/ML computational analysis algorithms implemented can be applied and/or executed in a time-based manner, in that collected sensor data for specific time periods can be allocated to such time periods so as to determine power levels or sensor parameters. For example, control engine 200 can execute a Bayesian determination for a predetermined time span, at preset intervals (e.g., a 24 hour time span, every 8 hours, based on learned/understood usage patterns (e.g., water usage patterns, power usage patterns), so as to segment the day according to expected demands, which can be leveraged to determine, derive, extract or otherwise determine an amount of power needed in reserve to power one or more components.

In some embodiments and, optionally, in combination of any embodiment described above or below, a neural network technique may be one of, without limitation, feedforward neural network, radial basis function network, recurrent neural network, convolutional network (e.g., U-net) or other suitable network. In some embodiments and, optionally, in combination of any embodiment described above or below, an implementation of Neural Network may be executed as follows:
a. define Neural Network architecture/model for the control framework,
b. transfer the input data to the neural network model,
c. train the model incrementally,
d. determine the accuracy for a specific number of timesteps,
e. apply the trained model to process the newly received input data,
f. optionally and in parallel, continue to train the trained model with a predetermined periodicity.

In some embodiments and, optionally, in combination of any embodiment described above or below, the trained AI model may specify a neural network by at least a neural network topology, a series of activation functions, and connection weights. For example, the topology of a neural network may include a configuration of nodes of the neural network and connections between such nodes. In some embodiments and, optionally, in combination of any embodiment described above or below, the trained AI model may also be specified to include other parameters, including but not limited to, bias values/functions and/or aggregation functions. For example, an activation function of a node may be a step function, sine function, continuous or piecewise linear function, sigmoid function, hyperbolic tangent function, or other type of mathematical function that represents a threshold at which the node is activated. In some embodiments and, optionally, in combination of any embodiment described above or below, the aggregation function may be a mathematical function that combines (e.g., sum, product, and the like) input signals to the node. In some embodiments and, optionally, in combination of any embodiment described above or below, an output of the aggregation function may be used as input to the activation function. In some embodiments and, optionally, in combination of any embodiment described above or below, the bias may be a constant value or function that may be used by the aggregation function and/or the activation function to make the node more or less likely to be activated.

FIG. 7 is a schematic diagram illustrating a client device showing an example embodiment of a client device that may be used within the present disclosure and/or the framework illustrated in FIG. 1. Client device 700 may include many more or less components than those shown in FIG. 7, such as a plurality of computers. However, the components shown are sufficient to disclose an illustrative embodiment for implementing the present disclosure. Client device 700 may represent, for example, UE 102, AP device 123, and/or controller 120, discussed above at least in relation to FIG. 1.

As shown in the figure, in some embodiments, client device 700 includes one or more processors (CPU) 722 in communication with one or more non-transitory computer readable media 730 via a bus 724. Client device 700 also includes a power supply 726, one or more network interfaces 750, an audio interface 752, a display 754, a keypad 756, an illuminator 758, an input/output interface 760, a haptic interface 762, an optional global positioning systems (GPS) receiver 764 and a camera(s) or other optical, thermal or electromagnetic sensors 766. Device 700 can include one camera/sensor 766, or a plurality of cameras/sensors 766, as understood by those of skill in the art. Power supply 726 provides power to Client device 700.

Client device 700 may optionally communicate with a base station (not shown), or directly with another computing device. In some embodiments, network interface 750 is sometimes known as a transceiver, transceiving device, or network interface card (NIC).

Audio interface 752 is arranged to produce and receive audio signals such as the sound of a human voice in some embodiments. Display 754 may be a liquid crystal display (LCD), gas plasma, light emitting diode (LED), or any other type of display used with a computing device. Display 754 may also include a touch sensitive screen arranged to receive input from an object such as a stylus or a digit from a human hand.

Keypad 756 may include any input device arranged to receive input from a user. Illuminator 758 may provide a status indication and/or provide light.

Client device 700 also includes input/output interface 760 for communicating with external. Input/output interface 760 can utilize one or more communication technologies, such as USB, infrared, Bluetooth™, or the like in some embodiments. Haptic interface 762 is arranged to provide tactile feedback to a user of the client device.

Optional GPS transceiver 764 can determine the physical coordinates of client device 700 on the surface of the Earth, which typically outputs a location as latitude and longitude values. GPS transceiver 764 can also employ other geo-positioning mechanisms, including, but not limited to, triangulation, assisted GPS (AGPS), E-OTD, CI, SAI, ETA, BSS or the like, to further determine the physical location of client device 700 on the surface of the Earth. In one embodiment, however, client device may through other components, provide other information that may be employed to determine a physical location of the device, including for example, a MAC address, Internet Protocol (IP) address, or the like.

Mass memory 730 includes a RAM 732, a ROM 734, and/or other non-transitory storage means. Mass memory 730 illustrates another example of computer storage media for storage of information such as computer readable instructions, data structures, program modules, usage data, or other data. Mass memory 730 stores a basic input/output system (“BIOS”) 740 for controlling low-level operation of client device 700. The mass memory also stores an operating system 741 for controlling the operation of client device 700.

Memory 730 further includes one or more data stores, which can be utilized by client device 700 to store, among other things, applications 742 for executing transformation engine 200, and/or other information or data. For example, data stores may be employed to store information that describes various capabilities of client device 700. The information may then be provided to another device based on any of a variety of events, including being sent as part of a header (e.g., index file of the HLS stream) during a communication, sent upon request, or the like. At least a portion of the capability information may also be stored on a disk drive or other storage medium (not shown) within client device 700.

Applications 742 may include computer executable instructions which, when executed by client device 700, transmit, receive, and/or otherwise process audio, video, images, and enable telecommunication with a server and/or another user of another client device. Applications 742 may further include a client that is configured to send, to receive, and/or to otherwise process gaming, goods/services and/or other forms of data, messages and content hosted and provided by the platform associated with control engine 200 and its affiliates.

In some embodiments, the system can be described as including one or more of a gas burner platform, a thermoelectric device, and one or more electronic devices. In some embodiments, the gas burner platform is configured to produce heat. In some embodiments, the thermoelectric device comprises a hot side and a cold side. In some embodiments, the thermoelectric device is configured to generate electrical power through a temperature difference between the hot side and the cold side. In some embodiments, the hot side of the thermoelectric device is configured to absorb the heat produced by a heat producing source, such as the wall of a furnace, or a gas exhaust, as non-limiting examples. As discussed supra, the system is applicable to any type of heat producing system, and therefore does not require the thermoelectric device to receive power from only a flame. In some embodiments, the hot side of the thermoelectric device is configured to absorb the heat produced by a flame. In some embodiments, the cold side of the thermoelectric device is coupled to a heat sink. In some embodiments, the one or more electronic devices receive the electrical power only from power generated by the thermoelectric device.

In some embodiments, the thermoelectric device includes two or more thermopiles. In some embodiments, the two or more thermopiles are connected in series. In some embodiments, the thermoelectric device includes one or more of bismuth telluride, lead telluride, silicon-germanium, skutterudites, half-heulser alloys, and tin selenide, which enable to the thermopiles and/or thermocouples to generate enough power to supply the components described herein.

In some embodiments, the gas burner platform is coupled to a hot water heater. In some embodiments, the one or more electronic devices include a valve actuator. In some embodiments, the one or more electronic devices include a powered anode. In some embodiments, a powered anode includes a non-sacrificial material (e.g., titanium). In some embodiments, a powered anode (rod) includes a sacrificial anode (rod) configured to use electricity to slow the degradation process. In some embodiments, the one or more electronic devices include a Wi-Fi transceiver. In some embodiments, the one or more electronic devices include a battery.

In some embodiments, the gas burner platform is configured to produce the heat intermittently to heat water in the hot water heater. In some embodiments, the battery is configured to store the electrical power produced when the heat is being produced. In some embodiments, the battery is configured to power one or more other electronic devices when the heat is not being produced. In some embodiments, the one or more electronic devices include a camera. In some embodiments, the one or more electronic devices include a controller. In some embodiments, the one or more electronic devices includes a computer and an access point device.

As used herein, the term “engine” identifies at least one software component and/or a combination of at least one software component and at least one hardware component which are designed/programmed/configured to manage/control other software and/or hardware components (such as the libraries, software development kits (SDKs), objects, and the like).

Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth. In some embodiments, the one or more processors may be implemented as a Complex Instruction Set Computer (CISC) or Reduced Instruction Set Computer (RISC) processors; x86 instruction set compatible processors, multi-core, or any other microprocessor or central processing unit (CPU). In various implementations, the one or more processors may be dual-core processor(s), dual-core mobile processor(s), and so forth.

Computer-related systems, computer systems, and systems, as used herein, include any combination of hardware and software. Examples of software may include software components, programs, applications, operating system software, middleware, firmware, software modules, routines, subroutines, functions, methods, procedures, software interfaces, application program interfaces (API), instruction sets, computer code, computer code segments, words, values, symbols, or any combination thereof. Determining whether some embodiment are implemented using hardware elements and/or software elements may vary in accordance with any number of factors, such as desired computational rate, power levels, heat tolerances, processing cycle budget, input data rates, output data rates, memory resources, data bus speeds and other design or performance constraints.

For the purposes of this disclosure a module is a software, hardware, or firmware (or combinations thereof) system, process or functionality, or component thereof, that performs or facilitates the processes, features, and/or functions described herein (with or without human interaction or augmentation). A module can include sub-modules. Software components of a module may be stored on a computer readable medium for execution by a processor. Modules may be integral to one or more servers or be loaded and executed by one or more servers. One or more modules may be grouped into an engine or an application.

One or more aspects of some embodiments may be implemented by representative instructions stored on a machine-readable medium which represents various logic within the processor, which when read by a machine causes the machine to execute logic to perform the techniques described herein. Such representations, known as “IP cores,” may be stored on a tangible, machine readable medium and supplied to various customers or manufacturing facilities to load into the fabrication machines that make the logic or processor. Of note, various embodiments described herein may, of course, be implemented using any appropriate hardware and/or computing software languages (e.g., C++, Objective-C, Swift, Java, JavaScript, Python, Perl, QT, and the like).

For example, exemplary software specifically programmed in accordance with one or more principles of the present disclosure may be downloadable from a network, for example, a website, as a stand-alone product or as an add-in package for installation in an existing software application. For example, exemplary software specifically programmed in accordance with one or more principles of the present disclosure may also be available as a client-server software application, or as a web-enabled software application. For example, exemplary software specifically programmed in accordance with one or more principles of the present disclosure may also be embodied as a software package installed on a hardware device.

For the purposes of this disclosure the term “user”, “subscriber” “provider”, “supplier”, or “customer” should be understood to refer to a user of an application or applications as described herein and/or a consumer of data supplied by a data provider. By way of example, and not limitation, the term “user” or “subscriber” can refer to a person who receives data provided by the data or service provider over the Internet in a browser session, or can refer to an automated software application which receives the data and stores or processes the data. Those skilled in the art will recognize that the methods and systems of the present disclosure may be implemented in many manners and as such are not to be limited by some embodiments and examples. In other words, functional elements being performed by single or multiple components, in various combinations of hardware and software or firmware, and individual functions, may be distributed among software applications at either the client level or server level or both. In this regard, any number of the features of some embodiments described herein may be combined into single or multiple configurations, and some embodiments having fewer than, or more than, all of the features described herein are possible.

“Substantially” and “approximately” when used in conjunction with a value encompass a difference of 5% or less of the same unit and/or scale of that being measured.

“Simultaneously” as used herein includes lag and/or latency times associated with a conventional and/or proprietary computer, such as processors and/or networks described herein attempting to process multiple types of data at the same time. “Simultaneously” also includes the time it takes for digital signals to transfer from one physical location to another, be it over a wireless and/or wired network, and/or within processor circuitry.

As used herein, “can” or “may” or derivations thereof (e.g., the system display can show X) are used for descriptive purposes only and is understood to be synonymous and/or interchangeable with “configured to” (e.g., the computer is configured to execute instructions X) when defining the metes and bounds of the system. The phrase “configured to” also denotes the step of configuring a structure or computer to execute a function according to some embodiments.

Functionality may also be, in whole or in part, distributed among multiple components, in manners now known or to become known. Thus, myriad software/hardware/firmware combinations are possible in achieving the functions, features, interfaces and preferences described herein. Moreover, the scope of the present disclosure covers conventionally known manners for carrying out the described features and functions and interfaces, as well as those variations and modifications that may be made to the hardware or software or firmware components described herein as would be understood by those skilled in the art now and hereafter.

Furthermore, some embodiments of computer implemented methods presented and described as flowcharts in this disclosure are provided by way of non-limiting example in order to provide a more complete understanding of the technology. The disclosed methods are not limited to the operations and logical flow presented herein. Some embodiments are contemplated in which the order of the various operations is altered and in which sub-operations described as being part of a larger operation are performed independently.

While some embodiments have been described for purposes of this disclosure, such embodiments should not be deemed to limit the teaching of this disclosure to those embodiments. Various changes and modifications may be made to the elements and operations described above to obtain a result that remains within the scope of the systems and processes described in this disclosure.

What is claimed is:

1. A system comprising:
a gas burner platform,
a thermoelectric device, and
one or more electronic devices,
wherein the gas burner platform is configured to produce a flame,
wherein the thermoelectric device comprises a hot side and a cold side,
wherein the thermoelectric device is configured to generate electrical power through a temperature difference between the hot side and the cold side,
wherein the hot side of the thermoelectric device is configured to absorb heat produced by the flame,
wherein the cold side of the thermoelectric device is coupled to a heat sink, and
wherein the one or more electronic devices receive the electrical power only from power generated by the thermoelectric device.

2. The system of claim 1, wherein the thermoelectric device includes two or more thermopiles.

3. The system of claim 2, wherein the two or more thermopiles are connected in series.

4. The system of claim 1, wherein the thermoelectric device includes one or more of bismuth telluride, lead telluride, silicon-germanium, skutterudites, half-heulser alloys, or tin selenide.

5. The system of claim 1, wherein the gas burner platform is coupled to a hot water heater.

6. The system of claim 5, wherein the one or more electronic devices include a valve actuator.

7. The system of claim 5, wherein the one or more electronic devices include a powered anode.

8. The system of claim 5, wherein the one or more electronic devices include a radio transceiver.

9. The system of claim 5, wherein the one or more electronic devices include a battery.

10. The system of claim 9, wherein the gas burner platform is configured to produce the heat intermittently to heat water in the hot water heater.

11. The system of claim 10, wherein the battery is configured to store the electrical power produced when the heat is being produced.

12. The system of claim 11, wherein the battery is configured to power one or more other electronic devices when the heat is not being produced.

13. The system of claim 5, wherein the one or more electronic devices include a camera.

14. The system of claim 5, wherein the one or more electronic devices include a controller.

15. The system of claim 5, wherein the one or more electronic devices includes a computer and an access point device.

16. A system comprising:
a gas burner platform,
a thermoelectric device, and
one or more electronic devices,
wherein the gas burner platform is configured to produce heat,
wherein the thermoelectric device comprises a hot side and a cold side,
wherein the thermoelectric device is configured to generate electrical power through a temperature difference between the hot side and the cold side, and
wherein the one or more electronic devices receive the electrical power from power generated by the thermoelectric device.

17. The system of claim 16, wherein the hot side of the thermoelectric device is configured to absorb the heat produced by the gas burner platform.

18. The system of claim 17, wherein the cold side of the thermoelectric device is coupled to a heat sink.

19. The system of claim 16, wherein the thermoelectric device includes two or more thermopiles, wherein the two or more thermopiles are connected in series.

20. The system of claim 16, wherein the thermoelectric device includes one or more of bismuth telluride, lead telluride, silicon-germanium, skutterudites, half-heulser alloys, or tin selenide.
